(19) United States
(12) Patent Application Publication
(10) Pub. No.: US 2025/0344401 A1
(43) Pub. Date: Nov. 6, 2025

(54) MAGNETIC MEMORY DEVICE AND METHOD OF FABRICATING THE SAME

(71) Applicant: SAMSUNG ELECTRONICS CO., LTD., SUWON-SI (KR)

(72) Inventors: KYOUNGHUN RYU, Suwon-si (KR); JUNGHWAN PARK, Suwon-si (KR); HIDEO SATO, Suwon-si (KR); KILHO LEE, Suwon-si (KR); JAE WOOK LEE, Suwon-si (KR); WOO CHANG LIM, Suwon-si (KR); KYUNGIL HONG, Suwon-si (KR)

(21) Appl. No.: 18/940,987

(22) Filed: Nov. 8, 2024

(30) Foreign Application Priority Data
May 2, 2024 (KR) 10-2024-0058748

(51) Int. Cl. H10B 61/00; H10N 50/01; H10N 50/10; H10N 50/85

(52) U.S. Cl. CPC H10B 61/10; H10N 50/01; H10N 50/10; H10N 50/85

(57) ABSTRACT

A magnetic memory device may include a first magnetic pattern and a second magnetic pattern sequentially stacked on a substrate. A tunnel barrier pattern is disposed between the first magnetic pattern and the second magnetic pattern. A bottom electrode is disposed between the substrate and the first magnetic pattern. A blocking pattern is disposed between the bottom electrode and the first magnetic pattern. The blocking pattern including a first blocking pattern that includes a first non-magnetic metal and nitrogen, and a second blocking pattern disposed on the first blocking pattern. The second blocking pattern includes the first non-magnetic metal and oxygen. A seed pattern is disposed between the second blocking pattern and the first magnetic pattern. The second blocking pattern has an amorphous phase.

### CROSS-REFERENCE TO RELATED APPLICATIONS

This application claims priority under 35 U.S.C. § 119 to Korean Patent Application No. 10-2024-0058748, filed on May 2, 2024 in the Korean Intellectual Property Office, the disclosure of which is incorporated by reference in its entirety herein.

### 1. TECHNICAL FIELD

Embodiments of the present disclosure relate to a magnetic memory device including a magnetic tunnel junction and a method of fabricating the same.

### 2. DISCUSSION OF RELATED ART

As the demand for electronic devices with increased speed and/or reduced power consumption increases, the demand for semiconductor memory devices with faster operating speeds and/or lower operating voltages has also increased. Research is being conducted concerning a magnetic memory device as a semiconductor memory device to satisfy this demand. Due to a high speed operation and/or nonvolatility, magnetic memory devices are emerging as a next-generation semiconductor memory device.

In general, the magnetic memory device includes a magnetic tunnel junction (MTJ) pattern. The MTJ pattern includes two magnetic layers and an insulating layer interposed therebetween. An electric resistance of the MTJ pattern may vary depending on magnetization directions of the magnetic layers. For example, the electric resistance of the MTJ pattern is higher when magnetization directions of the magnetic layers are anti-parallel to each other than when they are parallel to each other. This difference in electric resistance can be used for data writing/reading operations of the magnetic memory device.

There is an increased demand for magnetic memory devices with a high integration density and/or a low power consumption property along with the advancement of the electronics industry. Research is being conducted to increase the reliability of the magnetic memory device.

### SUMMARY

An embodiment of the present inventive concept provides a magnetic memory device including a magnetic pattern having a crystal structure with increased properties, and a method of fabricating the same.

An embodiment of the present inventive concept provides a magnetic memory device with increased high-temperature reliability and a method of fabricating the same.

According to an embodiment of the present inventive concept, a magnetic memory device may include a first magnetic pattern and a second magnetic pattern sequentially stacked on a substrate. A tunnel barrier pattern is disposed between the first magnetic pattern and the second magnetic pattern. A bottom electrode is disposed between the substrate and the first magnetic pattern. A blocking pattern is disposed between the bottom electrode and the first magnetic pattern. The blocking pattern including a first blocking pattern that includes a first non-magnetic metal and nitrogen, and a second blocking pattern disposed on the first blocking pattern. The second blocking pattern includes the first non-magnetic metal and oxygen. A seed pattern is disposed between the second blocking pattern and the first magnetic pattern. The second blocking pattern has an amorphous phase.

According to an embodiment of the present inventive concept, a magnetic memory device includes a first magnetic pattern and a second magnetic pattern sequentially stacked on a substrate. A tunnel barrier pattern is disposed between the first magnetic pattern and the second magnetic pattern. A bottom electrode is disposed between the substrate and the first magnetic pattern. A blocking pattern is disposed between the bottom electrode and the first magnetic pattern. The blocking pattern comprises a first blocking pattern and a second blocking pattern on the first blocking pattern. A seed pattern is disposed between the second blocking pattern and the first magnetic pattern. The first blocking pattern comprises tantalum nitride (TaN). The second blocking pattern comprises tantalum oxynitride (TaON). The seed pattern covers a top surface of the second blocking pattern.

According to an embodiment of the present inventive concept, a method of fabricating a magnetic memory device includes forming a first blocking layer on a substrate. The first blocking layer comprises a bottom electrode layer and a tantalum nitride layer sequentially stacked on the substrate. An oxidation process is performed on the first blocking layer to form a second blocking layer on the first blocking layer. The second blocking layer includes tantalum oxynitride (TaON). A seed layer is formed to cover a top surface of the second blocking layer. A first magnetic layer, a tunnel barrier layer, a second magnetic layer, a non-magnetic layer, and a capping layer is sequentially formed on the seed layer. The bottom electrode layer, the first blocking layer, the second blocking layer, the seed layer, the first magnetic layer, the tunnel barrier layer, the second magnetic layer, the non-magnetic layer, and the capping layer are etched using an etch mask to form a bottom electrode and a magnetic tunnel junction pattern including a first blocking pattern, a second blocking pattern, a seed pattern, a first magnetic pattern, a tunnel barrier pattern, a second magnetic pattern, a non-magnetic pattern, and a capping pattern. The first blocking pattern has a crystalline phase. The second blocking pattern has an amorphous phase.

### BRIEF DESCRIPTION OF THE DRAWINGS

FIG. 1 is a circuit diagram illustrating a unit memory cell of a magnetic memory device according to an embodiment of the present inventive concept.

FIG. 2 is a cross-sectional view illustrating a magnetic memory device according to an embodiment of the present inventive concept.

FIG. 3 is an enlarged cross-sectional view illustrating a portion ‘P’ of FIG. 2 according to an embodiment of the present inventive concept.

FIGS. 4 and 5 are graphs, each of which shows a change of an oxygen concentration in a second blocking pattern of a magnetic memory device according to embodiments of the present inventive concept.

FIG. 6 is a plan view illustrating a magnetic memory device according to an embodiment of the present inventive concept.

FIG. 7 is a cross-sectional view taken along a line I-I′ of FIG. 6 according to an embodiment of the present inventive concept.

FIGS. 8 to 12 are cross-sectional views illustrating a method of fabricating a magnetic memory device according to embodiments of the present inventive concept.

### DETAILED DESCRIPTION OF EMBODIMENTS

Example embodiments of the present inventive concepts will now be described more fully with reference to the accompanying drawings, in which non-limiting embodiments are shown.

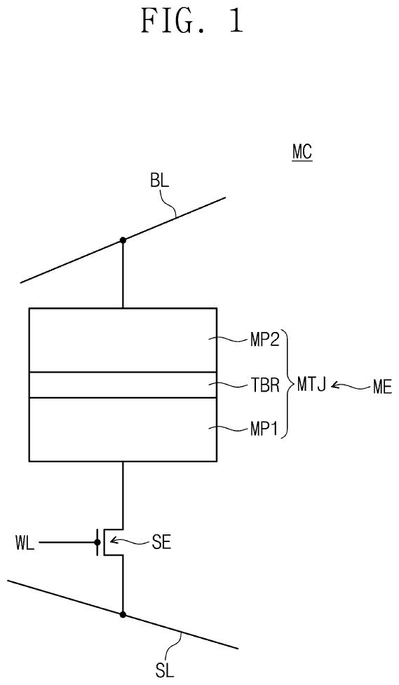

FIG. 1 is a circuit diagram illustrating a unit memory cell of a magnetic memory device according to an embodiment of the present inventive concept.

Referring to FIG. 1, in an embodiment a unit memory cell MC may include a memory element ME and a selection element SE. The memory device ME and the selection element SE may be electrically connected to each other in series. The memory device ME may be provided between and connected to (e.g., electrically connected thereto) a bit line BL and the selection element SE. The selection element SE may be provided between and connected to the memory device ME and a source line SL and may be controlled by a word line WL. In an embodiment, the selection element SE may include, for example, a bipolar transistor or a metal-oxide-semiconductor (MOS) field effect transistor.

In an embodiment, the memory element ME may include a magnetic tunnel junction pattern MTJ, and the magnetic tunnel junction pattern MTJ may include a first magnetic pattern MP1, a second magnetic pattern MP2, and a tunnel barrier pattern TBR between the first and second magnetic patterns MP1 and MP2. In an embodiment, one of the first and second magnetic patterns MPI and MP2 may be a fixed magnetic pattern, which has a fixed magnetization direction, regardless of the presence or absence of an external magnetic field generated under a typical usage environment. The other of the first and second magnetic patterns MP1 and MP2 may be a free magnetic pattern, having a magnetization direction that can be changed to one of two stable magnetization directions by an external magnetic field. The electric resistance of the magnetic tunnel junction pattern MTJ may be much greater when magnetization directions of the fixed and free magnetic patterns are antiparallel than when they are parallel. For example, the electric resistance of the magnetic tunnel junction pattern MTJ may be controlled by adjusting the magnetization direction of the free magnetic pattern. Thus, a difference in electric resistance of the magnetic tunnel junction pattern MTJ, which is caused by a difference in magnetization direction between the fixed and free magnetic patterns, may be used as a data storing mechanism in the memory element ME or the unit memory cell MC.

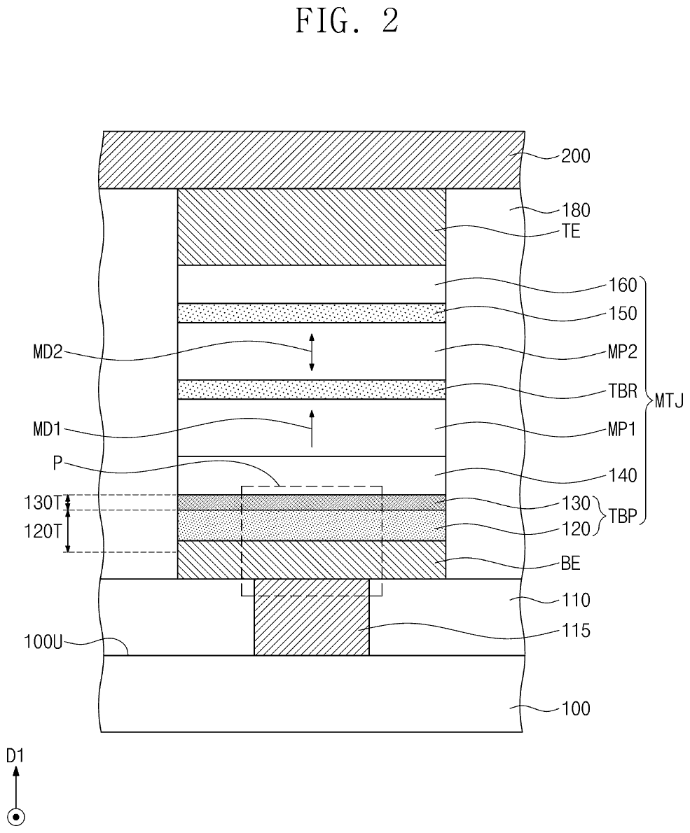

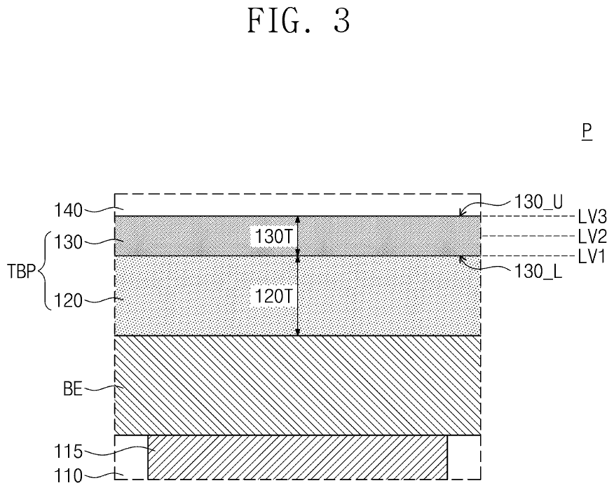

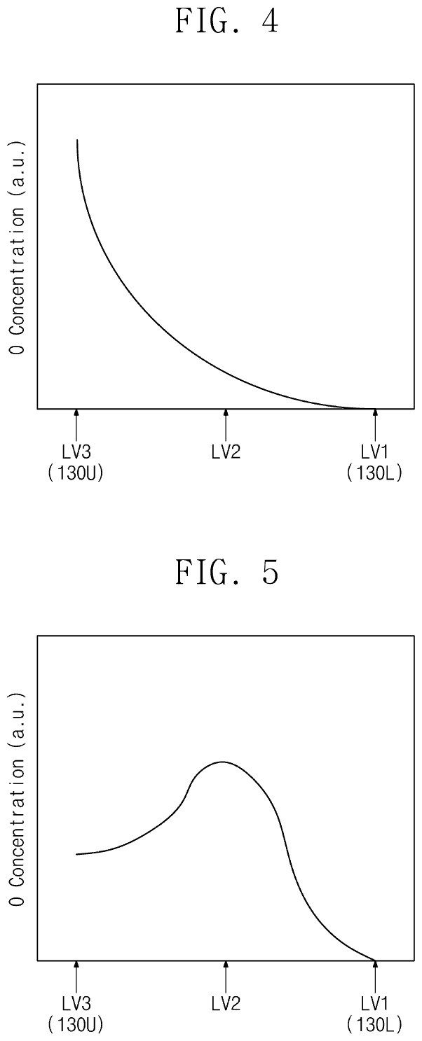

FIG. 2 is a cross-sectional view illustrating a magnetic memory device according to an embodiment of the present inventive concept. FIG. 3 is an enlarged cross-sectional view illustrating a portion ‘P’ of FIG. 2. FIGS. 4 and 5 are graphs, each showing a change of an oxygen concentration in a second blocking pattern 130 of a magnetic memory device according to an embodiment of the present inventive concept.

Referring to FIG. 2, a first interlayer insulating layer 110 may be disposed on a substrate 100 (e.g., disposed directly thereon in a first direction D1), and a lower contact plug 115 may be disposed in the first interlayer insulating layer 110. In an embodiment, the substrate 100 may be a semiconductor substrate, which is formed of or includes at least one of silicon (Si), silicon germanium (SiGe), germanium (Ge), or gallium arsenide (GaAs), or may be a silicon-on-insulator (SOI) wafer. The first interlayer insulating layer 110 may be formed of or include at least one of silicon oxide, silicon nitride, and/or silicon oxynitride.

The lower contact plug 115 may be arranged to penetrate the first interlayer insulating layer 110 and may directly contact the substrate 100 to be electrically connected to the substrate 100. A selection element (e.g., SE of FIG. 1) may be disposed in the substrate 100. In an embodiment, the selection element may be a field effect transistor. The lower contact plug 115 may be electrically connected to one of terminals (e.g., source/drain terminals) of the selection element. In an embodiment, the lower contact plug 115 may be formed of or include at least one of doped semiconductor materials (e.g., doped silicon), metallic materials (e.g., tungsten, titanium, and/or tantalum), metal-semiconductor compounds (e.g., metal silicide), and conductive metal nitrides (e.g., titanium nitride, tantalum nitride, and/or tungsten nitride).

A bottom electrode BE, a magnetic tunnel junction pattern MTJ, and a top electrode TE may be sequentially formed on the lower contact plug 115 in a first direction D1 that is perpendicular to a top surface 100U of the substrate 100. The bottom electrode BE may be disposed between the lower contact plug 115 and the magnetic tunnel junction pattern MTJ (e.g., in the first direction D1), and the magnetic tunnel junction pattern MTJ may be disposed between the bottom electrode BE and the top electrode TE (e.g., in the first direction D1).

The bottom electrode BE may be electrically connected to the lower contact plug 115. In an embodiment, the top electrode TE may be formed of or include at least one of metallic materials (e.g., Ta, W, Ru, and Ir) or conductive metal nitrides (e.g., TiN).

In an embodiment, the bottom electrode BE may be formed of or include at least one of conductive metal nitrides (e.g., titanium nitride or tantalum nitride). The top electrode TE may be formed of or include at least one of metallic materials (e.g., Ta, W, Ru, and Ir) or conductive metal nitrides (e.g., TiN).

In an embodiment, the magnetic tunnel junction pattern MTJ may include the first magnetic pattern MP1, the second magnetic pattern MP2, the tunnel barrier pattern TBR between the first and second magnetic patterns MP1 and MP2 (e.g., in the first direction D1), a blocking pattern TBP between the bottom electrode BE and the first magnetic pattern MP1 (e.g., in the first direction D1), and a seed pattern 140 on the blocking pattern TBP (e.g., disposed directly thereon in the first direction D1).

In an embodiment, the blocking pattern TBP may include a first blocking pattern 120 and a second blocking pattern 130. The first blocking pattern 120 and the second blocking pattern 130 may be sequentially stacked on the bottom electrode BE (e.g., in the first direction D1). For example, a top surface of the bottom electrode BE may be in direct contact with the first blocking pattern 120, and a top surface of the first blocking pattern 120 may be in direct contact with the second blocking pattern 130.

In an embodiment, the first blocking pattern 120 may include a first non-magnetic metal and nitrogen. For example, the first blocking pattern 120 may include a nitride material containing the first non-magnetic metal. In an embodiment, the first non-magnetic metal may be tantalum (Ta), and the first blocking pattern 120 may be made of tantalum nitride (TaN). The first blocking pattern 120 may have a crystalline phase. However, embodiments of the present inventive concept are not necessarily limited thereto. For example, in an embodiment the first non-magnetic metal may include at least one of tungsten (W), niobium (Nb), chromium (Cr), molybdenum (Mo), aluminum (Al), ruthenium (Ru), or vanadium (V).

The second blocking pattern 130 may include the first non-magnetic metal and oxygen. In an embodiment, the second blocking pattern 130 may include tantalum oxide (TaO). The second blocking pattern 130 may further include nitrogen. In an embodiment, the second blocking pattern 130 may be an element, which is formed as a result of an oxidation of the first blocking pattern 120, and in an embodiment, the second blocking pattern 130 may be made of tantalum oxynitride (TaON). The second blocking pattern 130 may have an amorphous phase.

For example, referring to FIGS. 2 and 3, the first and second blocking patterns 120 and 130 may have thicknesses 120T and 130T, respectively, when measured in the first direction D1 perpendicular to a top surface of the substrate 100. The thickness 130T of the second blocking pattern 130 may be less than the thickness 120T of the first blocking pattern 120. For example, in an embodiment the thickness 130T of the second blocking pattern 130 may be in a range of about 5 Å to about 50 Å. For example, in an embodiment the thickness 130T of the second blocking pattern 130 may be in a range of about 10 Å to about 30 Å. In an embodiment, the thickness 120T of the first blocking pattern 120 may be in a range of about 50 Å to about 100 Å.

In an embodiment, an oxygen concentration in the second blocking pattern 130 may have a non-uniform value. The oxygen concentration in the second blocking pattern may have a non-uniform value as a vertical distance from a top surface 130_U of the second blocking pattern 130 is changed. For example, the oxygen concentration in the second blocking pattern 130 may vary depending on a vertical level (e.g., a level in the first direction D1). As an example, the 10 oxygen concentration may have different values at a third level LV3 of the top surface 130_U of the second blocking pattern 130, a first level LV1 of a bottom surface 130_L of the second blocking pattern 130, and a second level LV2 between the top and bottom surfaces 130_U and 130_L of the second blocking pattern 130.

Referring to FIGS. 3 and 4, the oxygen concentration in the second blocking pattern 130 may gradually decrease as a distance from the top surface 130_U of the second blocking pattern 130 increases. For example, the oxygen concentration in the second blocking pattern 130 may gradually decrease from the third level LV3 to the first level LV1. In an embodiment, the oxygen concentration in the second blocking pattern 130 may have the greatest value at the third level LV3 and may have the smallest value at the first level LV1. The oxygen concentration at the first level 20 LVI may converge to zero. The profile of the oxygen concentration shown in FIG. 4 may be a result obtained by applying one of methods of forming the second blocking pattern 130, which will be described below.

Referring to FIGS. 3 and 5, in an embodiment the oxygen concentration in the second blocking pattern 130 may have the greatest value at a level between the top and bottom surfaces 130_U and 130_L of the second blocking pattern 130. As an example, the oxygen concentration in the second blocking pattern 130 may have the greatest value at the second level LV2 and may have the smallest value at the first level LV1. The oxygen concentration at the first level LV1 may converge to zero. The profile of the oxygen concentration shown in FIG. 5 may be a result obtained by applying another one of the methods of forming the second blocking pattern 130.

According to an embodiment of the present inventive concept, the blocking pattern TBP, which is composed of only the first blocking pattern 120 and the second blocking pattern 130, may be made of nitrogen-based materials (e.g., tantalum nitride (TaN) and tantalum oxynitride (TaON)) and may not include boron. Since nitrogen has a shorter diffusion length than boron at a high temperature, the blocking pattern TBP including the metal nitride may be more advantageous for high temperature processes than the blocking pattern TBP including the metal boride. For example, the magnetic memory device including the magnetic tunnel junction pattern MTJ may have increased reliability at a high temperature.

In addition, according to an embodiment of the present inventive concept, an additional layer containing hafnium or hafnium oxide may not be disposed between the seed pattern 140 and the bottom electrode BE, and the blocking pattern TBP is a hafnium-free material that may not include hafnium (Hf) or hafnium oxide. In a comparative embodiment in which the hafnium or the hafnium oxide is present, the free magnetic pattern of the first and second magnetic patterns MP1 and MP2 may have a magnetization direction aligned in a specific direction, and this may make it difficult to change the magnetization direction of the free magnetic pattern. In contrast, according to an embodiment of the present inventive concept, since the blocking pattern TBP may not include hafnium (Hf), the magnetization direction of the free magnetic pattern in the magnetic memory device may be easily changed.

Furthermore, even when an additional hafnium oxide is not disposed between the seed pattern 140 and the bottom electrode BE, the second blocking pattern 130 of an amorphous phase may be provided to have a sufficiently large thickness. Thus, it may be possible to prevent the bottom electrode BE from affecting the crystal structure of the seed pattern 140 and thereby to prevent the crystal structure and orientation of the first magnetic pattern MP1 from being affected by the crystal structure of the bottom electrode BE through the seed pattern 140. In an embodiment, even when a high-temperature process (e.g., at a temperature of 400° C. or higher) is performed on the magnetic tunnel junction pattern MTJ, the second blocking pattern 130 may be maintained to the amorphous phase, and thus, it may be possible to prevent the bottom electrode BE from affecting the crystal structure of the seed pattern 140.

Referring back to FIG. 2, the seed pattern 140 may be disposed between the second blocking pattern 130 and the first magnetic pattern MP1. The seed pattern 140 may include a material that contributes to crystal growth of the first magnetic pattern MP1. In an embodiment, the seed pattern 140 may be formed of or include at least one of chromium (Cr), iridium (Ir), or ruthenium (Ru).

The first magnetic pattern MP1, the tunnel barrier pattern TBR, and the second magnetic pattern MP2 may be sequentially stacked on the seed pattern 140 (e.g., in the first direction D1).

In an embodiment, the first magnetic pattern MP1 may be a fixed magnetic pattern having a fixed magnetization direction MD1, and the second magnetic pattern MP2 may be a free magnetic pattern having a variable magnetization direction MD2. The magnetization direction MD2 of the second magnetic pattern MP2 may be changed to be parallel or antiparallel to the magnetization direction MD1 of the first magnetic pattern MP1. FIG. 2 illustrates an example, in which the first and second magnetic patterns MP1 and MP2 are used as the fixed and free magnetic patterns, respectively. However, embodiments of the present inventive concept are not necessarily limited thereto. For example, in an embodiment the first magnetic pattern MP1 may serve as the free magnetic pattern, and the second magnetic pattern MP2 may serve as the fixed magnetic pattern.

In an embodiment, the magnetization directions MD1 and MD2 of the first and second magnetic patterns MP1 and MP2 may be perpendicular to an interface between the first magnetic pattern MP1 and the tunnel barrier pattern TBR and may be perpendicular to the top surface 100U of the substrate 100. In this embodiment, each of the first and second magnetic patterns MP1 and MP2 may be formed of or include at least one of intrinsic and extrinsic perpendicular magnetic materials. The intrinsic perpendicular magnetic material may include a material exhibiting a perpendicular magnetization property, even when there is no external cause. In an embodiment, the intrinsic perpendicular magnetic material may include at least one of i) perpendicular magnetic materials (e.g., CoFeTb, CoFeGd, and CoFeDy), ii) perpendicular magnetic materials with L10 structure, iii) CoPt-based materials with hexagonal-close-packed structure, or iv) perpendicular magnetic structures. In an embodiment, the perpendicular magnetic material with the L10 structure may include at least one of L10 FePt, L10 FePd, L10 CoPd, or L10 CoPt. The perpendicular magnetic structures may include magnetic and non-magnetic layers that are alternatingly and repeatedly stacked (e.g., in the first direction D1). For example, the perpendicular magnetic structures may include at least one of (Co/Pt) n, (CoFe/Pt) n, (CoFe/Pd) n, (Co/Pd) n, (Co/Ni) n, (CoNi/Pt) n, (CoCr/Pt) n or (CoCr/Pd) n, where n is the number of pairs of the stacked layers. The extrinsic perpendicular magnetic material may include a material which exhibits an intrinsic in-plane magnetization property when there is no external cause but exhibits a perpendicular magnetization property by an external cause. For example, due to a magnetic anisotropy, which results from interfacial characteristics between the first or second magnetic pattern MP1 or MP2 and the tunnel barrier pattern TBR, the extrinsic perpendicular magnetic material may have the perpendicular magnetization property. In an embodiment, the extrinsic perpendicular magnetic material may be formed of or include, for example, CoFeB. In an embodiment, the first magnetic pattern MP1 may be a fixed magnetic pattern including the intrinsic perpendicular magnetic material, and the second magnetic pattern MP2 may be a free magnetic pattern including the extrinsic perpendicular magnetic material (e.g., CoFeB).

In an embodiment, each of the first and second magnetic patterns MP1 and MP2 may be formed of or include at least one of Co-based Heusler alloys. In an embodiment, the tunnel barrier pattern TBR may be formed of or include at least one of magnesium oxide, titanium oxide, aluminum oxide, magnesium-zinc oxide, or magnesium-boron oxide.

In an embodiment, the magnetic tunnel junction pattern MTJ may further include a capping pattern 160 between the second magnetic pattern MP2 and the top electrode TE (e.g., in the first direction D1) and a non-magnetic pattern 150 between the second magnetic pattern MP2 and the capping pattern 160 (e.g., in the first direction D1). In an embodiment, the non-magnetic pattern 150 may be formed of or include at least one of magnesium oxide, titanium oxide, aluminum oxide, magnesium-zinc oxide, or magnesium-boron oxide. In an embodiment, the non-magnetic pattern 150 may include the same material as the tunnel barrier pattern TBR. A magnetic anisotropy of the second magnetic pattern MP2 may be increased due to an magnetic anisotropy that is induced at an interface between the non-magnetic pattern 150 and the second magnetic pattern MP2. The capping pattern 160 may be used to prevent the second magnetic pattern MP2 from being deteriorated. In an embodiment, the capping pattern 160 may be formed of or include at least one of tantalum (Ta), aluminum (Al), copper (Cu), gold (Au), silver (Ag), titanium (Ti), tantalum nitride (TaN), or titanium nitride (TiN).

A second interlayer insulating layer 180 may be disposed on the first interlayer insulating layer 110 (e.g., disposed directly thereon in the first direction D1) and may cover the side surfaces of the bottom electrode BE, the magnetic tunnel junction pattern MTJ, and the top electrode TE. In an embodiment, the second interlayer insulating layer 180 may be formed of or include silicon oxide, silicon nitride, and/or silicon oxynitride.

An upper interconnection line 200 may be disposed on the second interlayer insulating layer 180 (e.g., disposed directly thereon in the first direction D1) and may be connected to (e.g., directly connected thereto) the top electrode TE. The upper interconnection line 200 may extend in a second direction D2 parallel to the top surface 100U of the substrate 100. The upper interconnection line 200 may be connected to (e.g., electrically connected thereto) the magnetic tunnel junction pattern MTJ through the top electrode TE and may be used as the bit line BL of FIG. 1. In an embodiment, the upper interconnection line 200 may be formed of or include at least one of metallic materials (e.g., copper) or conductive metal nitride materials.

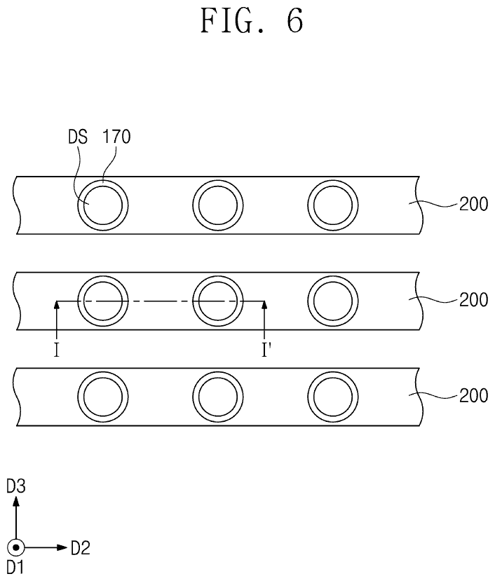

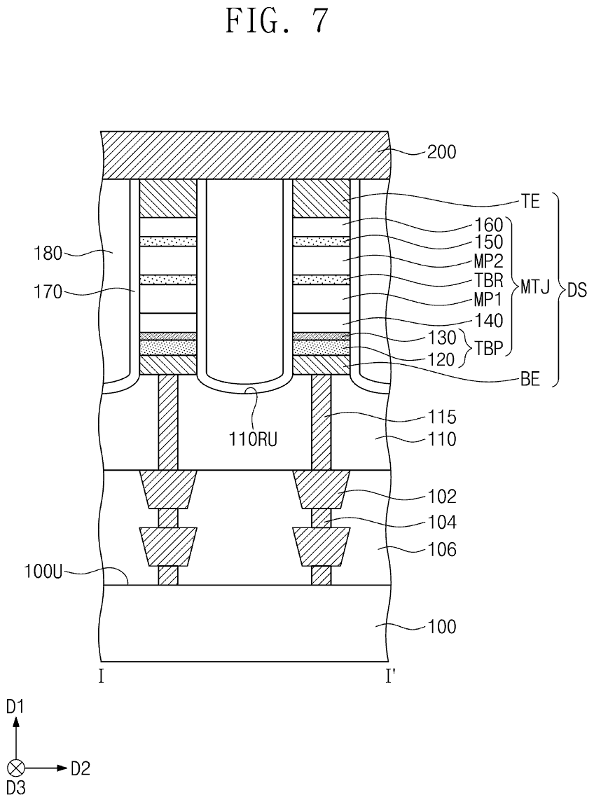

FIG. 6 is a plan view illustrating a magnetic memory device according to an embodiment of the present inventive concept. FIG. 7 is a cross-sectional view taken along a line I-I′ of FIG. 6. For the sake of brevity, the same element as that in the magnetic memory device described with reference to FIGS. 2 to 5 may be identified by the same reference number without repeating an overlapping description.

Referring to FIGS. 6 and 7, lower interconnection lines 102 and lower contacts 104 may be disposed on the substrate 100. The lower interconnection lines 102 may be spaced apart from the top surface 100U of the substrate 100 in the first direction DI perpendicular to the top surface 100U of the substrate 100. The lower contacts 104 may be disposed between the lower interconnection lines 102 (e.g., in the first direction D1) and between the lowermost ones of the lower interconnection lines 102 and the substrate 100 (e.g., in the first direction D1). Each of the lower interconnection lines 102 may be electrically connected to the substrate 100 through a corresponding one of the lower contacts 104. In an embodiment, the lower interconnection lines 102 and the lower contacts 104 may be formed of or include at least one of metallic materials (e.g., copper).

The selection elements SE of FIG. 1 may be disposed in the substrate 100. In an embodiment, the selection elements may be field effect transistors. Each of the lower interconnection lines 102 may be electrically connected to one of terminals (e.g., source/drain terminals) of a corresponding one of the selection elements through a corresponding one of the lower contacts 104.

A lower interlayer insulating layer 106 may be disposed on the substrate 100 to cover the lower interconnection lines 102 and the lower contacts 104. Top surfaces of the uppermost ones of the lower interconnection lines 102 may be coplanar (e.g., in the first direction D1) with a top surface of the lower interlayer insulating layer 106. The top surfaces of the uppermost ones of the lower interconnection lines 102 may be located at the same height as the top surface of the lower interlayer insulating layer 106. In the present specification, the term ‘height’ may mean a distance measured from the top surface 100U of the substrate 100 in the first direction D1. In an embodiment, the lower interlayer insulating layer 106 may include silicon oxide, silicon nitride, and/or silicon oxynitride.

The first interlayer insulating layer 110 may be disposed on (e.g., disposed directly thereon in the first direction D1) the lower interlayer insulating layer 106 to cover the top surfaces of the uppermost ones of the lower interconnection lines 102.

A plurality of lower contact plugs 115 may be disposed in the first interlayer insulating layer 110. The lower contact plugs 115 may be spaced apart from each other in second and third directions D2 and D3, which are parallel to the top surface 100U of the substrate 100. The second and third directions D2 and D3 may cross each other and are not parallel to each other. For example, in some embodiments the first to third directions D1 to D3 may be perpendicular to each other. Each of the lower contact plugs 115 may be provided to penetrate the first interlayer insulating layer 110 and may be connected to a corresponding one of the lower interconnection lines 102. In an embodiment, the lower contact plugs 115 may be formed of or include at least one of doped semiconductor materials (e.g., doped silicon), metallic materials (e.g., tungsten, titanium, and/or tantalum), metal-semiconductor compounds (e.g., metal silicide), or conductive metal nitride materials (e.g., titanium nitride, tantalum nitride, and/or tungsten nitride).

A plurality of data storage patterns DS may be disposed on the first interlayer insulating layer 110 (e.g., disposed directly thereon in the first direction D1) and may be spaced apart from each other in the second and third directions D2 and D3. The data storage patterns DS may be disposed on and connected to the lower contact plugs 115, respectively.

In an embodiment, each of the data storage patterns DS may include the bottom electrode BE, the magnetic tunnel junction pattern MTJ, and the top electrode TE, which are sequentially stacked on a corresponding one of the lower contact plugs 115. The bottom electrode BE may be disposed between the corresponding lower contact plug 115 and the magnetic tunnel junction pattern MTJ (e.g., in the first direction D1), and the magnetic tunnel junction pattern MTJ may be disposed between the bottom and top electrodes BE and TE (e.g., in the first direction D1). The magnetic tunnel junction pattern MTJ may be configured to have the same features as the magnetic tunnel junction patterns MTJ described with reference to FIGS. 2 to 5. In an embodiment, the magnetic tunnel junction pattern MTJ may include the first magnetic pattern MP1, the second magnetic pattern MP2, the tunnel barrier pattern TBR between the first magnetic pattern MPI and the second magnetic pattern MP2 (e.g., in the first direction D1), the blocking pattern TBP between the bottom electrode BE and the first magnetic pattern MP1 (e.g., in the first direction D1), the seed pattern 140 on the blocking pattern TBP, the capping pattern 160 between the second magnetic pattern MP2 and the top electrode TE (e.g., in the first direction D1), and the non-magnetic pattern 150 between the second magnetic pattern MP2 and the capping pattern 160 (e.g., in the first direction D1), as described with reference to FIG. 2.

In an embodiment, a top surface of the first interlayer insulating layer 110 between the data storage patterns DS may be recessed towards the substrate 100. A protection insulating layer 170 may be provided to enclose a side surface of each of the data storage patterns DS. The protection insulating layer 170 may cover the side surfaces of the bottom electrode BE, the magnetic tunnel junction pattern MTJ, and the top electrode TE and may enclose the side surfaces of the bottom electrode BE, the magnetic tunnel junction pattern MTJ, and the top electrode TE, when viewed in a plan view. The protection insulating layer 170 may extend from the side surface of each of the data storage patterns DS to a recessed top surface 110RU of the first interlayer insulating layer 110. The protection insulating layer 170 may conformally cover the recessed top surface 110RU of the first interlayer insulating layer 110. The protection insulating layer 170 may include a nitride material (e.g., silicon nitride).

The second interlayer insulating layer 180 may be disposed on (e.g., disposed directly thereon) the first interlayer insulating layer 110 to cover the data storage patterns DS. The protection insulating layer 170 may be interposed between (e.g., directly therebetween) the side surface of each of the data storage patterns DS and the second interlayer insulating layer 180 and may extend into a region between the recessed top surface 110RU of the first interlayer insulating layer 110 and the second interlayer insulating layer 180.

A plurality of upper interconnection lines 200 may be disposed on the second interlayer insulating layer 180 (e.g., disposed directly thereon in the first direction D1). The upper interconnection lines 200 may extend in the second direction D2 and may be spaced apart from each other in the third direction D3. Each of the upper interconnection lines 200 may be, for example, electrically connected to ones of the data storage patterns DS, which are spaced apart from each other in the second direction D2.

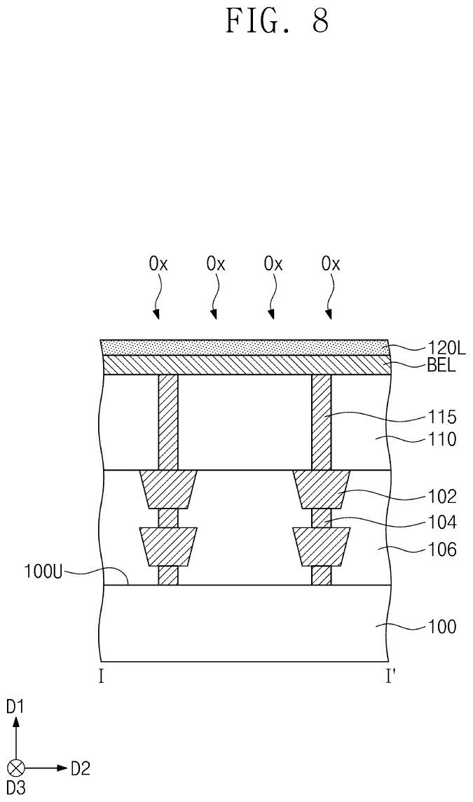

FIGS. 8 to 12 are cross-sectional views illustrating a method of fabricating a magnetic memory device according to embodiments of the present inventive concept.

Referring to FIG. 8, the selection elements (e.g., SE of FIG. 1) may be formed in the substrate 100, and the lower interconnection lines 102 and the lower contacts 104 may be formed on the substrate 100. In an embodiment, each of the lower interconnection lines 102 may be electrically connected to a terminal of a corresponding one of the selection elements through a corresponding one of the lower contacts 104. The lower interlayer insulating layer 106 may be formed on the substrate 100 (e.g., formed directly thereon in the first direction D1) to cover the lower interconnection lines 102 and the lower contacts 104. Top surfaces of the uppermost ones of the lower interconnection lines 102 may be coplanar (e.g., in the first direction D1) with the top surface of the lower interlayer insulating layer 106.

The first interlayer insulating layer 110 may be formed on the lower interlayer insulating layer 106 (e.g., formed directly thereon in the first direction D1), and a plurality of lower contact plugs 115 may be formed in the first interlayer insulating layer 110. Each of the lower contact plugs 115 may be provided to penetrate the first interlayer insulating layer 110 and may be connected to a corresponding one of the lower interconnection lines 102. In an embodiment, the formation of the lower contact plugs 115 may include forming lower contact holes to penetrate the first interlayer insulating layer 110, forming a lower contact layer on the first interlayer insulating layer 110 to fill the lower contact holes, and planarizing the lower contact layer to expose the top surface of the first interlayer insulating layer 110.

A bottom electrode layer BEL and a first blocking layer 120L may be sequentially formed on the first interlayer insulating layer 110 (e.g., in the first direction D1). In an embodiment, the bottom electrode layer BEL may be formed of or include at least one of conductive metal nitride materials (e.g., titanium nitride or tantalum nitride). The first blocking layer 120L may include a first non-magnetic metal and nitrogen and may include, for example, a nitride material containing the first non-magnetic metal. As an example, in an embodiment the first non-magnetic metal may be tantalum (Ta), and the first blocking layer 120L may be made of tantalum nitride (TaN).

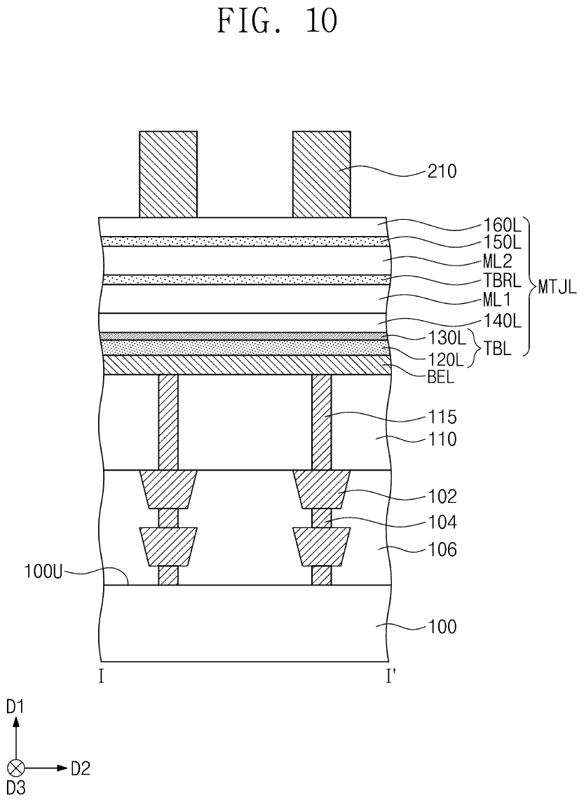

In an embodiment, the bottom electrode layer BEL may be deposited by a chemical vapor deposition method or a physical vapor deposition method, and a planarization process (e.g., a chemical mechanical polishing (CMP) process) may be performed on the bottom electrode layer BEL. After the formation of the lower contact plugs 115 is finished, the lower contact plugs 115 and the first interlayer insulating layer 110 may have uneven top surfaces, and in this case, the top surface of the bottom electrode layer BEL deposited thereon may have an uneven shape. However, as a result of the planarization process, the bottom electrode layer BEL may have a planarized top surface, and in this case, layers constituting a magnetic tunnel junction layer (e.g., see MTJL of FIG. 10) may be easily formed on the bottom electrode layer BEL. In an embodiment, the first blocking layer 120L may be formed on the bottom electrode layer BEL using a chemical vapor deposition method or a physical vapor deposition method (e.g., a sputtering deposition method).

In an embodiment, an oxidation process may then be performed on the first blocking layer 120L. In an embodiment, the oxidation process may be performed through a natural oxidation process in a chamber having a high oxygen concentration. In the case where the first blocking layer 120L is kept in the chamber at a specific temperature for a sufficiently long time, oxygen atoms may enter the first blocking layer 120L.

Alternatively, the oxidation process may be performed using a plasma injection process. The plasma injection process may be performed to inject oxygen atoms into the first blocking layer 120L to a specific depth.

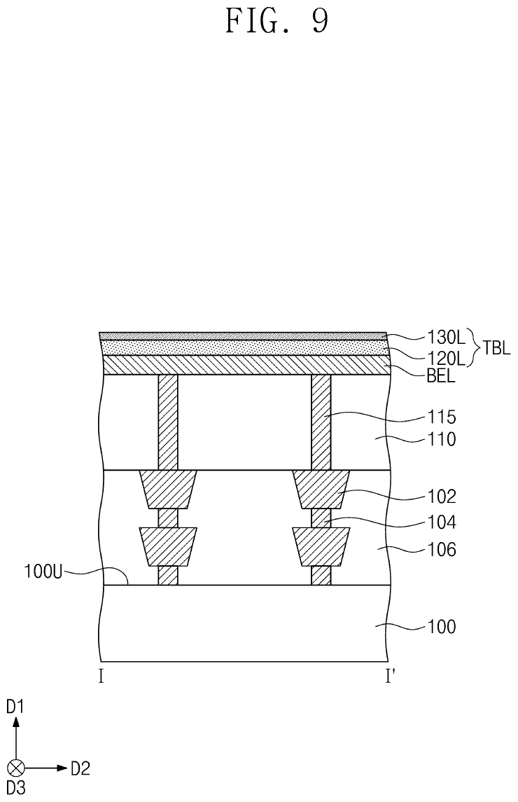

Referring to FIG. 9, an upper portion of the first blocking layer 120L may be oxidized by the oxidation process to form a second blocking layer 130L, and in this embodiment, the first and second blocking layers 120L and 130L may form a blocking layer TBL. The second blocking layer 130L may include the same elements as those in the first blocking layer 120L and may further include oxygen. As an example, the second blocking layer 130L may include the first non-magnetic metal and oxygen and may further include nitrogen. In an embodiment, the second blocking layer 130L may include tantalum oxide (TaO) or tantalum oxynitride (TaON).

In an embodiment in which the second blocking layer 130L is formed in the chamber through a natural oxidation process, an oxygen concentration in the second blocking layer 130L may have the concentration profile shown in FIG. 4. In an embodiment in which the second blocking layer 130L is formed by the plasma injection process, the oxygen concentration in the second blocking layer 130L may have the concentration profile shown in FIG. 5.

Referring to FIG. 10, a seed layer 140L may be formed to cover a top surface of the second blocking layer 130L, and a first magnetic layer ML1, a tunnel barrier layer TBRL, a second magnetic layer ML2, a non-magnetic layer 150L, and a capping layer 160L may be sequentially formed on the seed layer 140L (e.g., in the first direction D1). As a result, a magnetic tunnel junction layer MTJL may be formed. In an embodiment, the magnetic tunnel junction layer MTJL may include the first blocking layer 120L, the second blocking layer 130L, the seed layer 140L, the first magnetic layer ML1, the tunnel barrier layer TBRL, the second magnetic layer ML2, the non-magnetic layer 150L, and the capping layer 160L, which are sequentially stacked on the bottom electrode layer BEL (e.g., in the first direction D1).

In an embodiment, each of the seed layer 140L, the first magnetic layer ML1, the tunnel barrier layer TBRL, the second magnetic layer ML2, the non-magnetic layer 150L, and the capping layer 160L may be formed by a chemical vapor deposition method or a physical vapor deposition method (e.g., a sputtering deposition method). Thereafter, a thermal treatment process may be optionally performed on the magnetic tunnel junction layer MTJL.

A conductive mask pattern 210 may be formed on the magnetic tunnel junction layer MTJL to define a region where the magnetic tunnel junction pattern will be formed. In an embodiment, the conductive mask pattern 210 may be formed of or include at least one of metallic materials (e.g., Ta, W, Ru, and Ir) or conductive metal nitrides (e.g., TiN).

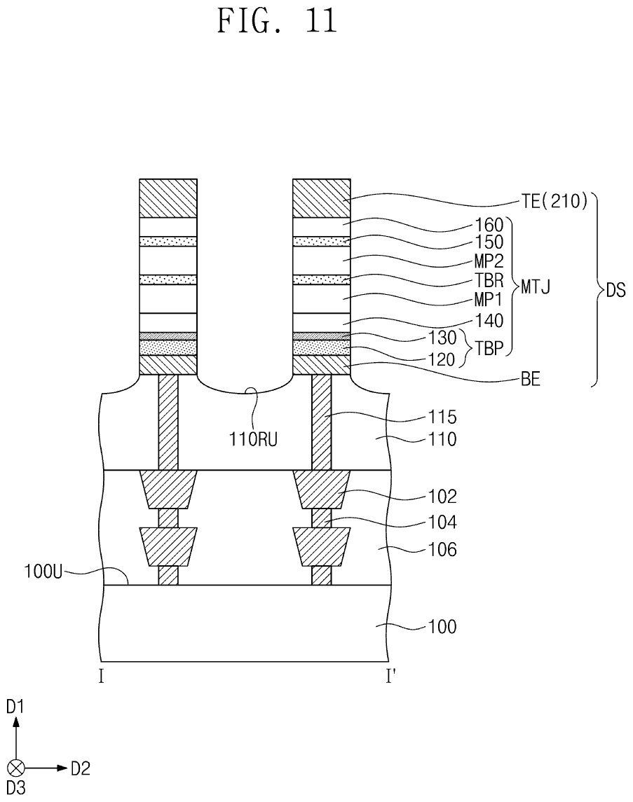

Referring to FIG. 11, in an embodiment the magnetic tunnel junction layer MTJL and the bottom electrode layer BEL may be sequentially etched using the conductive mask patterns 210 as an etch mask.

For example, the bottom electrode layer BEL, the first blocking layer 120L, the second blocking layer 130L, the seed layer 140L, the first magnetic layer ML1, the tunnel barrier layer TBRL, the second magnetic layer ML2, the non-magnetic layer 150L, and the capping layer 160L may be etched using the etch mask to form the magnetic tunnel junction patterns MTJ, each of which includes the bottom electrode BE, and the first blocking pattern 120, the second blocking pattern 130, the seed pattern 140, the first magnetic pattern MP1, the tunnel barrier pattern TBR, the second magnetic pattern MP2, the non-magnetic pattern 150, and the capping pattern 160.

In an embodiment, the process of etching the magnetic tunnel junction layer MTJL and the bottom electrode layer BEL may be an ion beam etching process using an ion beam. The ion beam may include inert ions. As a result of the etching process, the top surface of the first interlayer insulating layer 110 may be recessed, between the magnetic tunnel junction patterns MTJ. Thus, the first interlayer insulating layer 110 may have the recessed top surface 110RU, between the magnetic tunnel junction patterns MTJ.

After the etching process, a remaining portion of the conductive mask pattern 210 may be left on the magnetic tunnel junction pattern MTJ. The remaining portion of the conductive mask pattern 210 may serve as the top electrodes TE. Hereinafter, the remaining portions of the conductive mask patterns 210 may be referred to as the top electrodes TE. The top electrodes TE, the magnetic tunnel junction patterns MTJ, and the bottom electrodes BE may constitute the data storage patterns DS, and each of the data storage patterns DS may include the bottom electrode BE, the magnetic tunnel junction pattern MTJ, and the top electrode TE, which are sequentially stacked on a corresponding one of the lower contact plugs 115.

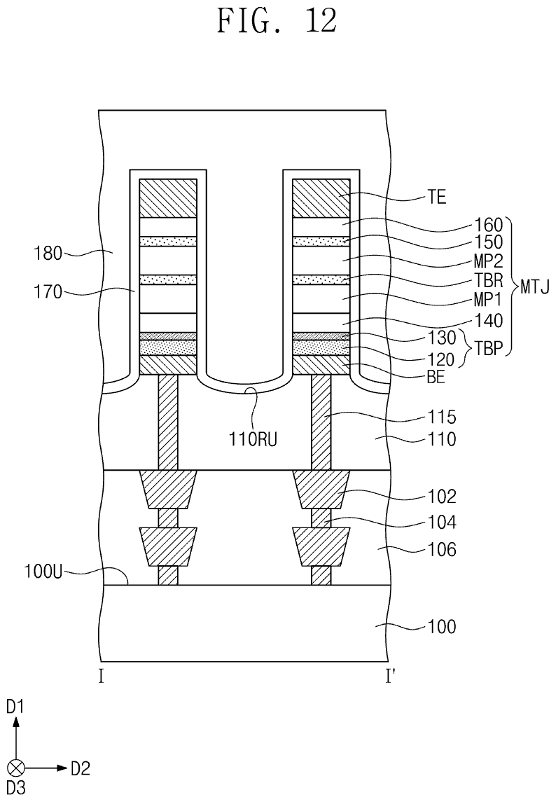

Referring to FIG. 12, the protection insulating layer 170 may be formed on (e.g., formed directly thereon in the first direction D1) the first interlayer insulating layer 110 to cover the data storage patterns DS. The protection insulating layer 170 may be formed to conformally cover the top and side surfaces of each of the data storage patterns DS and may extend along the recessed top surface 110RU of the first interlayer insulating layer 110. The second interlayer insulating layer 180 may be formed on (e.g., formed directly thereon) the protection insulating layer 170 to cover the data storage patterns DS.

Referring back to FIG. 7, the second interlayer insulating layer 180 and the protection insulating layer 170 may be partially removed to expose a top surface of the top electrode TE of each of the data storage patterns DS. The upper interconnection line 200 may be formed on the second interlayer insulating layer 180 to cover the exposed top surface of the top electrode TE. The upper interconnection line 200 may be electrically connected to the top electrode TE.

According to an embodiment of the present inventive concept, a blocking pattern including a first blocking pattern and a second blocking pattern may be disposed between a bottom electrode and a seed pattern. The second blocking pattern may have an amorphous phase and may have a sufficiently large thickness. Thus, it may be possible to prevent the bottom electrode from affecting a crystal structure of the seed pattern.

In addition, the blocking pattern may include metal nitride. Since nitrogen has a shorter mean diffusion length than other elements (e.g., boron) at a high temperature, the blocking pattern including the metal nitride may be relatively free from a diffusion issue in a high-temperature process. Accordingly, it may be possible to increase the high-temperature reliability of a magnetic memory device including a magnetic tunnel junction pattern (MTJ).

While non-limiting embodiments of the present inventive concept have been particularly shown and described, it will be understood by one of ordinary skill in the art that variations in form and detail may be made therein without departing from the spirit and scope of the present inventive concept.

What is claimed is:

1. A magnetic memory device, comprising:
a first magnetic pattern and a second magnetic pattern sequentially stacked on a substrate;
a tunnel barrier pattern disposed between the first magnetic pattern and the second magnetic pattern;
a bottom electrode disposed between the substrate and the first magnetic pattern;
a blocking pattern disposed between the bottom electrode and the first magnetic pattern, the blocking pattern comprising a first blocking pattern that includes a first non-magnetic metal and nitrogen, and a second blocking pattern disposed on the first blocking pattern, the second blocking pattern including the first non-magnetic metal and oxygen; and
a seed pattern disposed between the second blocking pattern and the first magnetic pattern,
wherein the second blocking pattern has an amorphous phase.

2. The magnetic memory device of claim 1, wherein the second blocking pattern further comprises nitrogen.

3. The magnetic memory device of claim 1, wherein:
the first non-magnetic metal comprises at least one of tantalum (Ta) or tungsten (W); and
the seed pattern comprises at least one of chromium (Cr), ruthenium (Ru), or iridium (Ir).

4. The magnetic memory device of claim 1, wherein the first blocking pattern has a crystalline phase.

5. The magnetic memory device of claim 1, wherein an oxygen concentration in the second blocking pattern has a non-uniform value as a vertical distance from a top surface of the second blocking pattern is changed.

6. The magnetic memory device of claim 5, wherein the oxygen concentration in the second blocking pattern decreases as a distance from the top surface of the second blocking pattern increases.

7. The magnetic memory device of claim 5, wherein the oxygen concentration in the second blocking pattern has a greatest value at a level between the top and bottom surfaces of the second blocking pattern.

8. The magnetic memory device of claim 1, wherein a thickness of the second blocking pattern is in a range of about 10 Å to about 30 Å in a first direction perpendicular to a top surface of the substrate.

9. The magnetic memory device of claim 1, wherein a thickness of the second blocking pattern is less than a thickness of the first blocking pattern in a first direction perpendicular to a top surface of the substrate.

10. The magnetic memory device of claim 1, wherein the blocking pattern is composed of a hafnium-free material.

11. The magnetic memory device of claim 1, wherein the seed pattern covers a top surface of the second blocking pattern.

12. The magnetic memory device of claim 1, further comprising:
a top electrode on the second magnetic pattern;
a capping pattern between the second magnetic pattern and the top electrode; and
a non-magnetic pattern between the second magnetic pattern and the capping pattern.

13. A magnetic memory device, comprising:
a first magnetic pattern and a second magnetic pattern sequentially stacked on a substrate;
a tunnel barrier pattern disposed between the first magnetic pattern and the second magnetic pattern;
a bottom electrode disposed between the substrate and the first magnetic pattern;
a blocking pattern disposed between the bottom electrode and the first magnetic pattern, the blocking pattern comprising a first blocking pattern and a second blocking pattern on the first blocking pattern; and
a seed pattern disposed between the second blocking pattern and the first magnetic pattern,
wherein the first blocking pattern comprises tantalum nitride (TaN),
the second blocking pattern comprises tantalum oxynitride (TaON), and
the seed pattern covers a top surface of the second blocking pattern.

14. The magnetic memory device of claim 13, wherein the second blocking pattern has a thickness in a first direction perpendicular to a top surface of the substrate in a range of about 10 Å to about 30 Å.

15. The magnetic memory device of claim 13, wherein an oxygen concentration in the second blocking pattern has a non-uniform value as a vertical distance from the top surface of the second blocking pattern is changed.

16. The magnetic memory device of claim 13, wherein the second blocking pattern has an amorphous phase.

17. The magnetic memory device of claim 13, wherein the seed pattern comprise at least one of chromium (Cr), ruthenium (Ru), or iridium (Ir).

18. The magnetic memory device of claim 13, wherein the blocking pattern is composed of a hafnium-free material.

19. A method of fabricating a magnetic memory device, comprising:
forming a first blocking layer on a substrate, the first blocking layer comprising a bottom electrode layer and a tantalum nitride layer sequentially stacked on the substrate;
performing an oxidation process on the first blocking layer to form a second blocking layer on the first blocking layer, the second blocking layer including tantalum oxynitride (TaON);
forming a seed layer to cover a top surface of the second blocking layer;
sequentially forming a first magnetic layer, a tunnel barrier layer, a second magnetic layer, a non-magnetic layer, and a capping layer on the seed layer; and
etching the bottom electrode layer, the first blocking layer, the second blocking layer, the seed layer, the first magnetic layer, the tunnel barrier layer, the second magnetic layer, the non-magnetic layer, and the capping layer using an etch mask to form a bottom electrode and a magnetic tunnel junction pattern including a first blocking pattern, a second blocking pattern, a seed pattern, a first magnetic pattern, a tunnel barrier pattern, a second magnetic pattern, a non-magnetic pattern, and a capping pattern,
wherein the first blocking pattern has a crystalline phase, and
the second blocking pattern has an amorphous phase.

20. The method of claim 19, wherein the second blocking pattern is formed to have a thickness in a range of about 10 Å to about 30 Å in a first direction perpendicular to a top surface of the substrate.
